(19) United States
(12) Patent Application Publication
(10) Pub. No.: US 2025/0374660 A1
(43) Pub. Date: Dec. 4, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wang-Chun Huang, Hsinchu (TW); Hou-Yu Chen, Hsinchu (TW); Jin CAI, Hsinchu (TW); Chih-Hao Wang, Hsinchu (TW)

(73) Assignee: Taiwan Semiconductor Manufacturing Company, Ltd., Hsinchu (TW)

(21) Appl. No.: 18/680,522

(22) Filed: May 31, 2024

(51) Int. Cl. H01L 27/06; H01L 29/06; H01L 29/423; H01L 29/66; H01L 29/775; H01L 29/786

(52) U.S. Cl. CPC H10D 84/811; H10D 1/692; H10D 30/014; H10D 30/031; H10D 30/43; H10D 30/6735; H10D 30/6757; H10D 62/121

(57) ABSTRACT

A semiconductor device and a method of manufacturing the semiconductor device are provided. The method includes the following steps. A plurality of first semiconductor layers and a plurality of second semiconductor layers alternately stacked over a substrate are formed. The second semiconductor layers are removed to form openings between the first semiconductor layers. A plurality of gate dielectric layers is formed, and each of the gate dielectric layers surrounds one of the first semiconductor layers respectively. A plurality of floating gate layers is formed, wherein the floating gate layers are electrically connected to each other and surround the gate dielectric layers respectively, and the gate dielectric layers are located between the first semiconductor layers and the floating gate layers respectively.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

A task to be solved is that a relatively large number of capacitors may be required to maintain the supply voltage within acceptable voltage fluctuation tolerances. This can increase the cost of the design, in that the capacitors take up overhead space on a semiconductor chip that could be utilized for more valuable functions.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows a three-dimensional schematic diagram of a gate-all-around (GAA) field effect transistor device.

FIGS. 2A-6A are cross-sectional side views of various stages of fabrication of a semiconductor device taken along line A-A of FIG. 1 according to some embodiments.

FIGS. 2B-6B are cross-sectional side views of various stages of fabrication of a semiconductor device taken along line B-B of FIG. 1 according to some embodiments.

FIGS. 7A-7D are schematic diagrams of a method of manufacturing a decoupling capacitor.

FIGS. 8A-8F are schematic diagrams of a method of manufacturing a decoupling capacitor that is compatible with a semiconductor manufacturing process.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor device of the present disclosure presents embodiments in the form of a multi-gate transistor or a fin multi-gate transistor, referred to herein as for example, GAA field-effect transistor (GAA-FET) device.

GAA-FET devices have become popular candidates for high performance and low leakage applications (e.g., for logic devices and/or circuits). In various examples, GAA-FET devices employ narrow fin widths for short channel control, improved Ion/Ioff ratio, and continuously variable gate lengths. Additionally, GAA-FET devices with multiple nanosheet channels have been used in high-speed applications, but such devices still suffer from increased current leakage and power consumption. Embodiments of the present disclosure can provide a decoupling capacitor without loss of channel inversion capacitance of GAA-FET device even at high frequency operation.

In general, a decoupling capacitor (referred to as decap) is a capacitor used to decouple (i.e., prevent electrical energy from transferring to) one part of a circuit from another. Noise causing by other circuit elements is shunted through the capacitor, reducing its effect on the rest of the circuit. Within these devices, some of them need to be affordable for high voltage operation which is categorized as IO decap. With device architecture change for higher logic density and better performance, the conventional approach of IO decap by depositing IO dielectric layer before dummy gate causes channel capacitance loss owing to no metal filled between semiconductor sheets. Another straightforward approach is directly depositing IO dielectric layer post deposition of a high-K layer, but it is shown that possible capacitance loss at high frequency operation owing to worse metal resistance with limited metal volume in space between sheet to sheet. In embodiments of the present disclosure, the device architecture for IO decap is proposed to be achieved by inserting of floating gate layers which are merged in the sheet-to-sheet spaces and capping by following IO dielectric layer (e.g., insulating layer) and gate electrode layer out of the sheet-to-sheet spaces. By this approach, the high channel inversion capacitance of GAA-FET device is kept even at high frequency operation owing to acceptable metal resistance in the sheet-to-sheet spaces and the semiconductor device itself is also affordable for high voltage operation because most of voltage drop is sharing by enough thick IO dielectric layer out of the sheet-to-sheet spaces and is less constrained in gap fill space.

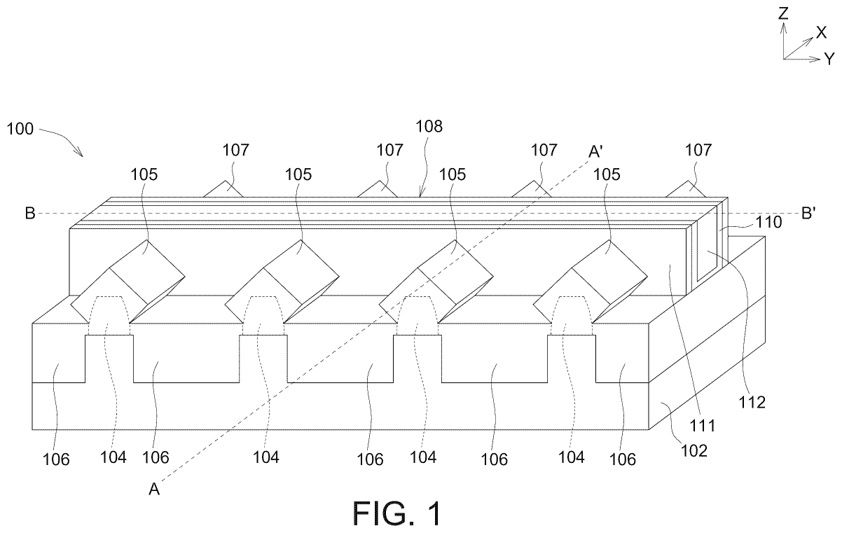

Referring to FIG. 1, a three-dimensional schematic diagram of a semiconductor device 100 is provided. The semiconductor device 100 is a gate-all-around field effect transistor. The semiconductor device 100 includes a substrate 102, multiple nanosheet channels 104 extending from the substrate 102, an isolation region 106, and a gate structure 108 disposed on and around the nanosheet channels 104. The substrate 102 may be a semiconductor substrate, such as a silicon substrate. The substrate 102 may include an insulating layer formed on the semiconductor substrate. The substrate 102 may include various doping configurations according to design requirements known in the art. The substrate 102 may also include other semiconductors, such as germanium, silicon carbide (SiC), silicon germanium (SiGe) or diamond. Alternatively, the substrate 102 may include compound semiconductors and/or alloy semiconductors. Furthermore, in some embodiments, the substrate 102 may include an epitaxial layer (epi-layer) or SOI (silicon-on-insulator) structure.

The nanosheet channels 104 may include silicon or other elemental semiconductors, such as germanium. Compound semiconductors include silicon carbide, gallium arsenide, gallium phosphide, indium phosphide, indium arsenide and/or indium antimonide. Alloy semiconductors include SiGe, GaAsP, AlInAs, AlGaAs, InGaAs, GaInP, and/or GaInAsP, or combinations thereof. The nanosheet channels 104 may be fabricated using suitable processes including photolithography and etch processes. The photolithography process may include forming a photoresist layer covering the substrate 102, exposing the photoresist layer to form a pattern by performing a post-exposure bake process, and a masking element is used to form the pattern included in the photoresist layer. In some embodiments, patterning the photoresist layer to form the fabricated device may be performed using an e-beam lithography process. The photoresist layer may be used to protect areas of the substrate 102, and then recesses are formed in the silicon layer during an etch process for leaving the extended nanosheet channels 104. The method of etching the recesses includes dry etching, wet etching and/or other suitable methods. The nanosheet channels 104 on the substrate 102 may also be formed using other embodiments.

Each of the plurality of nanosheet channels 104 includes a first source/drain region (i.e., source/drain feature) 105 and a second source/drain region (i.e., source/drain feature) 107, the first source/drain region 105 and the second source/drain region 107 are formed in, over and/or around the nanosheet channels 104. The source/drain regions 105 and 107 may be epitaxially grown on the nanosheet channels 104. The nanosheet channels 104 of the transistor is disposed within the gate structure 108 along a plane substantially parallel to the plane defined by section A-A′ of FIG. 1. In some examples, the nanosheet channels 104 include a high mobility material, such as germanium, any of the compound semiconductors or alloy semiconductors discussed above, and/or combinations thereof. High mobility materials include those materials that have greater electron mobility than silicon. For example, in some embodiments, the high mobility material may be a silicon-based material having an intrinsic electron mobility of about 1350 cm²/V-s and a hole mobility of about 480 cm²/V-s above room temperature (300K).

The isolation region 106 may be a shallow trench isolation (STI) feature, or a field oxide, a local oxidation of silicon (LOCOS) feature and/or other suitable isolation features on and/or within the substrate 102. The isolation region 106 can be composed of the following materials: silicon oxide, silicon nitride, silicon oxynitride, fluorine-doped silicate glass (FSG), low-k dielectrics, combinations thereof, and/or other suitable materials known in the art. In one embodiment, the STI feature can be formed into an isolation structure in the substrate 102 by etching trench technology. The trenches may then be filled with isolation material and subjected to a chemical mechanical polishing (CMP) process. In some embodiments, isolation region 106 may include a multi-layer structure, e.g., having one or more liner layers.

The gate structure 108 includes a gate stack, the gate stack includes a gate dielectric layer 110 and a gate electrode layer 112 formed above the gate dielectric layer 110. In some embodiments, the gate dielectric layer 110 may include an interfacial layer formed on the channel region and a high-K dielectric layer above the interfacial layer. The interface layer of the gate dielectric layer 110 may include a dielectric material, such as a silicon oxide layer (SiO₂) or a silicon oxynitride (SiON). The high-K dielectric layer of the gate dielectric layer 110 may include: HfO₂, TiO₂, HfZrO, Ta₂O₃, HfSiO₄, ZrO₂, ZrSiO₂, combinations thereof, or other suitable materials. In other embodiments, the gate dielectric layer 110 may include silicon dioxide or other suitable dielectrics. The gate dielectric layer 110 can be deposited by chemical oxidation, thermal oxidation, atomic layer deposition (ALD), physical vapor deposition (PVD), chemical vapor deposition (CVD) and/or other suitable methods.

The gate electrode layer 112 may include a conductive layer, for example, W, TIN, TaN, WN, Re, Ir, Ru, Mo, Al, Cu, Co, Ni, combinations thereof and/or other suitable compositions. In some embodiments, the gate electrode layer 112 may include a first group of metal materials for N-type device and a second group of metal materials for P-type device. Accordingly, the semiconductor device 100 may include a dual work-function metal gate configuration. For example, the first metallic material (for an N-type device) may comprise a metal having a work function substantially aligned with that of the substrate conduction band, or at least substantially aligned with a work function of the conduction band of the nanosheet channels 104. Likewise, for example, the second metallic material (for a P-type device) may comprise a metal having a work function substantially aligned with that of the valence band of the substrate, or at least substantially aligned with a work function of the valence band of the nanosheet channels 104. Accordingly, the gate electrode layer 112 may provide a gate electrode to the semiconductor device 100, including N-type and P-type devices. In some embodiments, the gate electrode layer 112 may include polysilicon layers alternately stacked. The gate electrode layer 112 may be formed using physical vapor deposition (PVD), chemical vapor deposition (CVD), electron beam evaporation, and/or other suitable processes. In some embodiments, sidewall spacers 111 are formed on sidewalls of the gate structure 108. The sidewall spacers 111 may include dielectric materials such as silicon oxide, silicon nitride, silicon carbide, silicon oxynitride or combinations thereof.

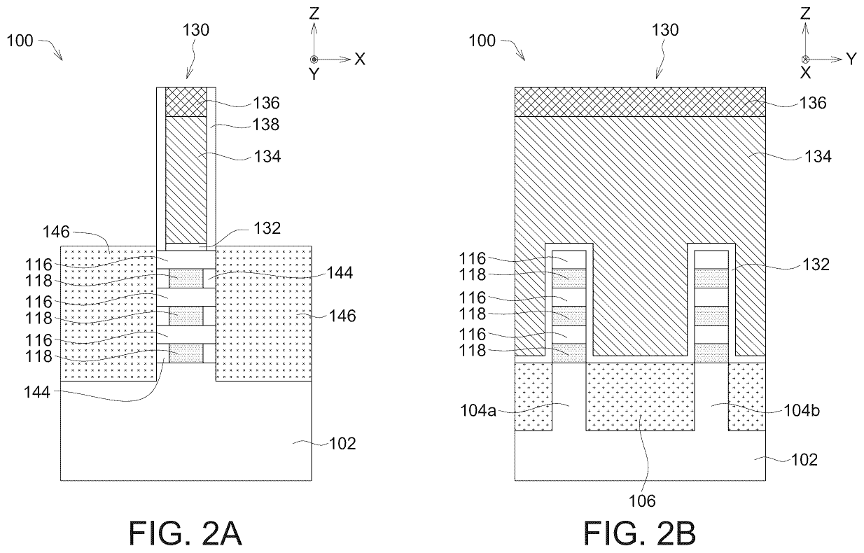

FIGS. 2A-6A are cross-sectional side views of various stages of fabrication of the semiconductor device 100 taken along line A-A′ of FIG. 1 in accordance with some embodiments. FIGS. 2B-6B are cross-sectional side views of various stages of fabrication of the semiconductor device 100 taken along line B-B′ of FIG. 1 in accordance with some embodiments. As shown in FIGS. 2A and 2B, epitaxial source/drain features 146 are formed in the source/drain regions. Epitaxial source/drain features 146 may be formed by epitaxial growth methods, such as using chemical vapor deposition (CVD), atomic layer deposition (ALD), or molecular beam epitaxy. Epitaxial source/drain features 146 may be grown vertically and horizontally to form facets, which may correspond to crystal planes of the material used for the substrate 102.

In some cases, the epitaxial source/drain features 146 may be grown beyond the topmost semiconductor channel (i.e., the first semiconductor layer 116 below the sacrificial gate structure 130) to contact with the gate spacers 138. The second semiconductor layer 118 beneath the sacrificial gate structure 130 is separated from the epitaxial source/drain features 146 by dielectric spacers 144.

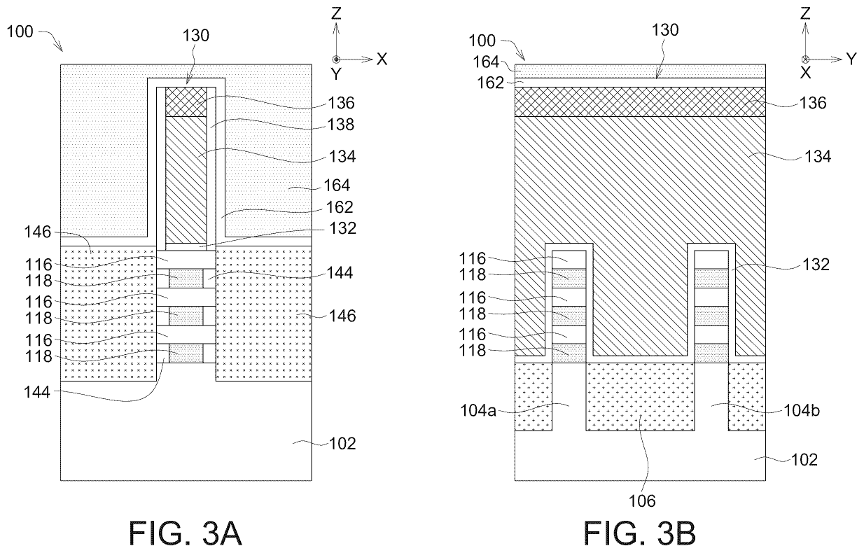

In FIGS. 3A to 3B, a contact etch stop layer (CESL) 162 is conformally formed on the exposed surface of the semiconductor device 100. The contact etch stop layer 162 covers the exposed sacrificial gate structure 130, the epitaxial source/drain features 146, and the STI (not shown) near the epitaxial source/drain features 146. The contact etch stop layer 162 may include an oxygen-containing material or a nitrogen-containing material, such as silicon nitride, silicon carbonitride, silicon oxynitride, silicon carbonitride, silicon oxide, silicon oxycarbide, the like, or combinations thereof, and may be formed by CVD, PECVD, ALD or any suitable deposition technique. Next, a first interlayer dielectric (ILD) 164 is formed on the contact etch stop layer 162 above the semiconductor device 100. The material of the first interlayer dielectric layer 164 may include compounds including silicon, oxygen, carbon and/or hydrogen, such as silicon oxide, ethyl orthosilicate oxide, SiCOH, and SiOC. The organic materials such as polymers may also be used for the first interlayer dielectric layer 164. The first interlayer dielectric layer 164 may be deposited by a PECVD process or other suitable deposition techniques. In some embodiments, after forming the first interlayer dielectric layer 164, the semiconductor device 100 may undergo a thermal process to anneal the first interlayer dielectric layer 164.

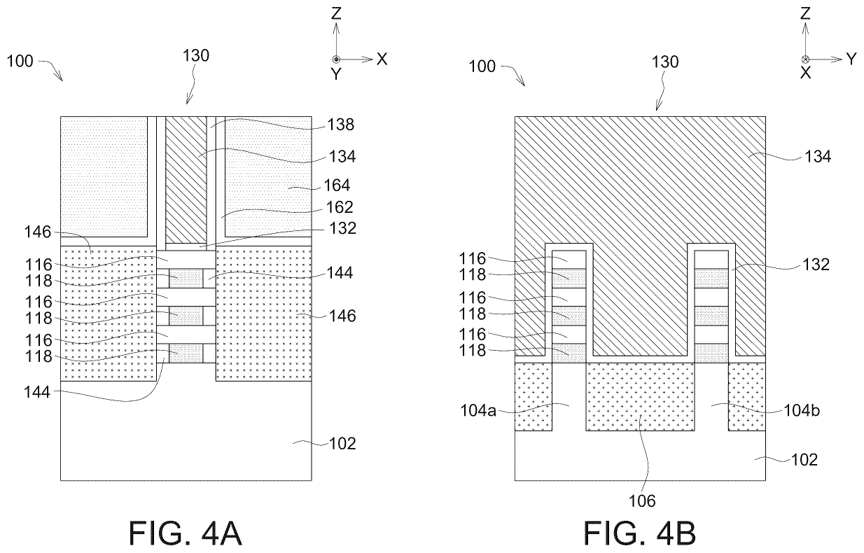

In FIGS. 4A and 4B, after the first interlayer dielectric layer 164 is formed, a planarization operation such as chemical mechanical polishing is performed on the semiconductor device 100 until the sacrificial gate electrode layer 134 is exposed.

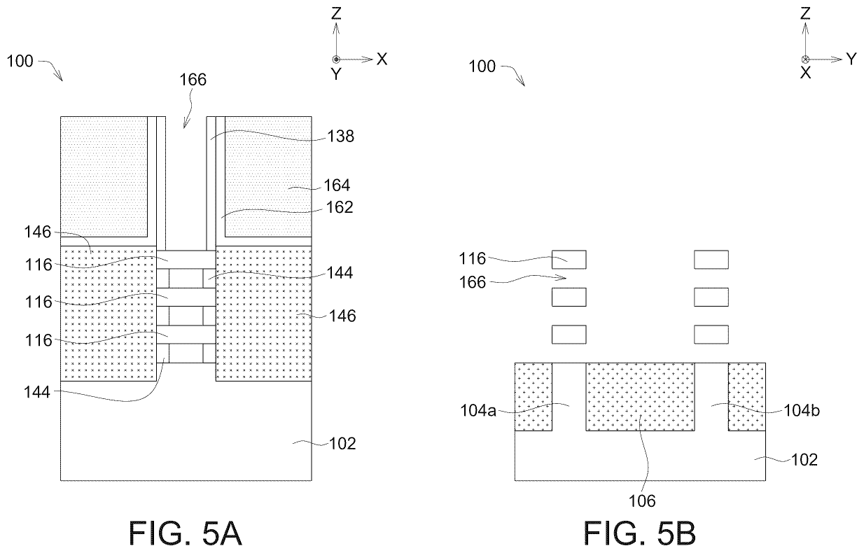

In FIGS. 5A and 5B, the sacrificial gate structure 130 and the second semiconductor layer 118 are removed. Removing the sacrificial gate structure 130 and the second semiconductor layer 118 forms openings 166 between the gate spacers 138 and between the first semiconductor layers 116 (i.e., sheet-to-sheet spaces). The interlayer dielectric layer 164 protects the epitaxial source/drain features 146 during the removal process. The sacrificial gate structure 130 may be removed using plasma dry etching and/or wet etching. The sacrificial gate electrode layer 134 may first be removed by any suitable process, such as dry etching, wet etching, or a combination thereof. The sacrificial gate dielectric layer 132 is then removed by performing any suitable process (such as dry etching, wet etching, or a combination thereof). In some embodiments, a wet etchant, such as a tetramethylammonium hydroxide solution, may be used to selectively remove the sacrificial gate electrode layer 134 but not the gate spacer 138, the interlayer electrical layer 164 and the contact etch stop layer 162.

A selective wet etching process may be used to remove portions of second semiconductor layer 118. In the case where the second semiconductor layer 118 is made of SiGe and the first semiconductor layer 116 is made of silicon, the chemicals used in the selective wet etch process may remove the SiGe while not substantially affecting silicon (the dielectric material of the gate spacer 138 and dielectric spacers 144). In one embodiment, a wet etchant such as, but not limited to, hydrofluoric acid (HF), nitric acid (HNO₃), hydrochloric acid (HCl), and phosphoric acid (H₃PO₄), or a dry etchant, such as a fluorine-based or chlorine-based gas or any suitable isotropic etchant, is used to remove the second semiconductor layer 118.

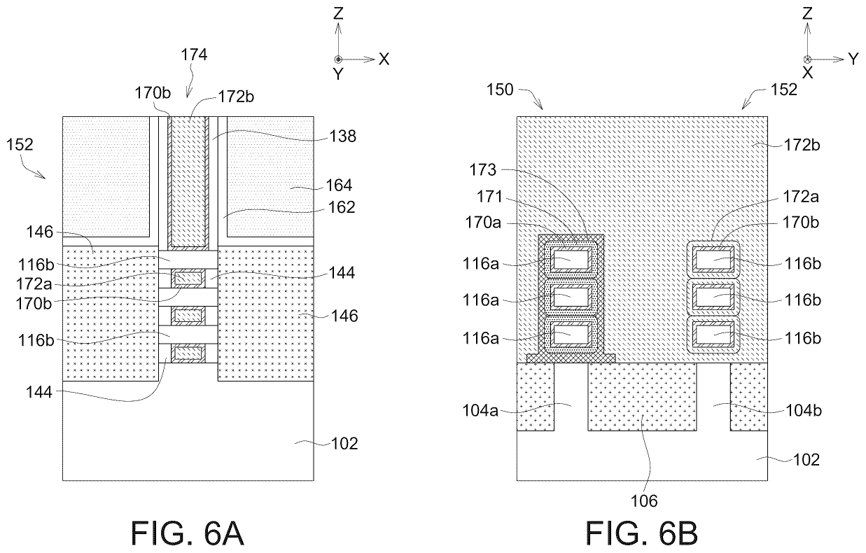

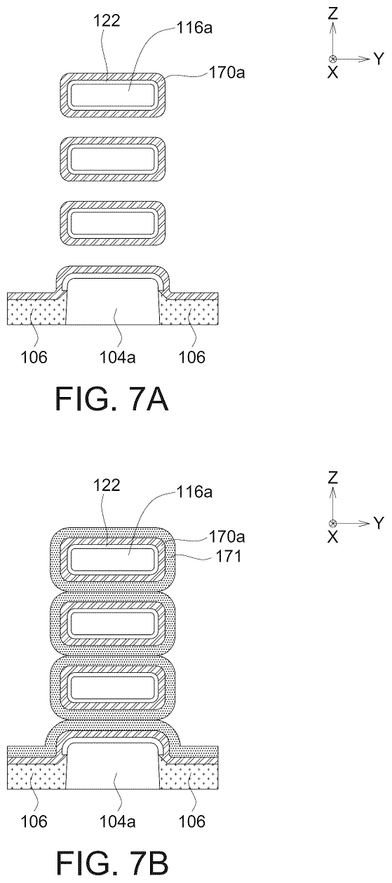

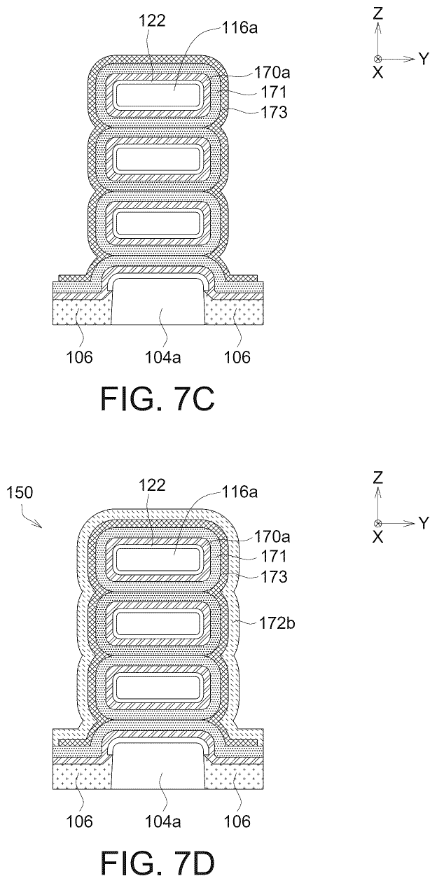

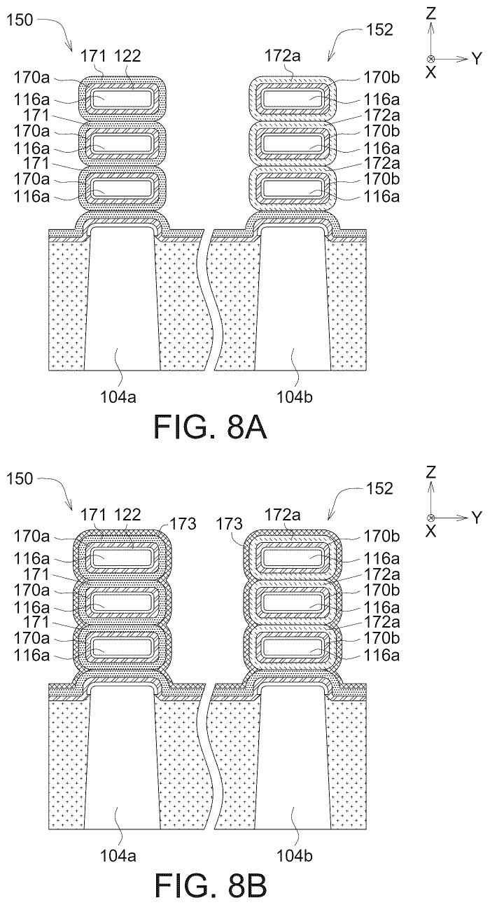

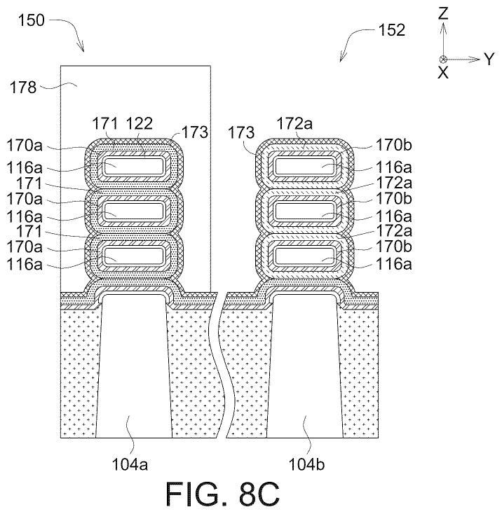

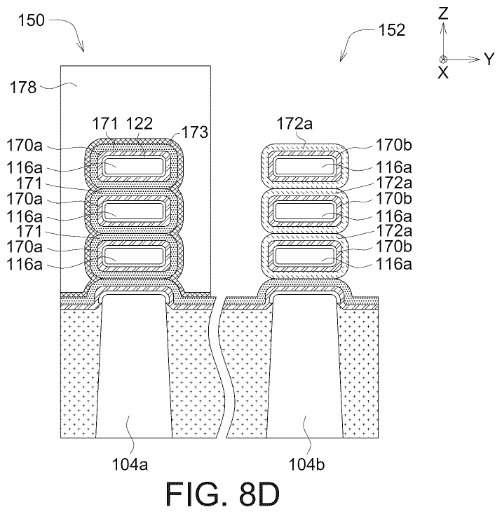

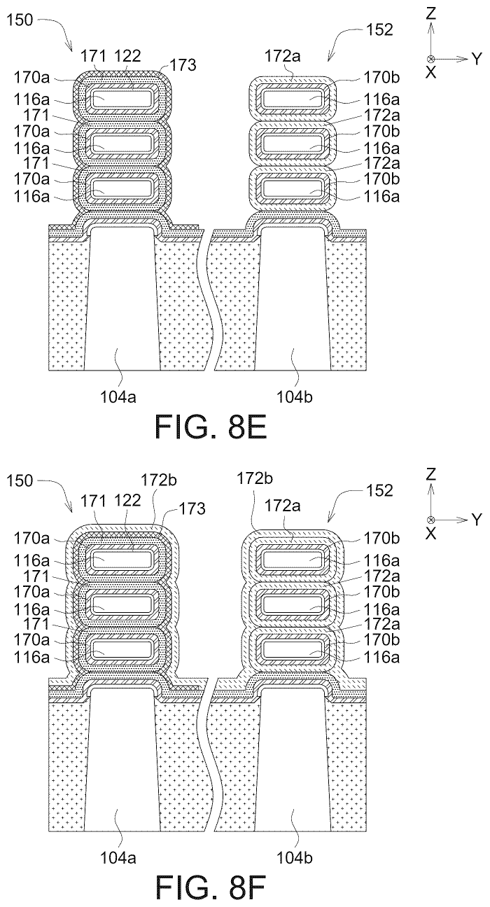

In FIGS. 6A and 6B, after forming the nanostructure channels (i.e., the exposed first semiconductor layers 116a), a decoupling capacitor 150 and a gate-all-around structure 152 are formed in the gap refilling space. The decoupling capacitor 150 includes a plurality of first semiconductor layers 116a, a plurality of first gate dielectric layers 170a, a plurality of floating gate layers 171, an insulating layer 173 and a second gate electrode layer 172b on the first fin structure 104a. The gate-all-around structure 152 includes a plurality of first channel layers 116b, a plurality of second gate dielectric layers 170b, a plurality of first gate electrode layers 172a and a second gate electrode layer 172b disposed on the second fin structure 104b. The decoupling capacitor 150 and the gate-all-around structure 152 can be completed using a compatible semiconductor process to merge the floating gate layers 171 into the space between the first semiconductor layers 116a and the floating gate layers 171 is capped with the insulating layer 173 and the second gate electrode layer 172b. For the manufacturing method of the decoupling capacitor 150, please refer to FIGS. 7A to 7D and FIGS. 8A to 8F.

As shown in FIG. 6B, the first gate dielectric layers 170a respectively surround the first semiconductor layers 116a, and the second gate dielectric layers 170b respectively surround the first channel layer 116b. The first semiconductor layer 116a and the first channel layer 116b may be made of the same material and formed simultaneously in the same process. In addition, the floating gate layers 171 are electrically connected to each other and respectively surround the first gate dielectric layers 170a, and the first gate electrode layers 172a are electrically connected to each other and respectively surround the second gate dielectric layer 170b. The floating gate layers 171 and the first gate electrode layers 172a may be made of the same material and formed simultaneously in the same process. In addition, the first gate dielectric layer 170a and the second gate dielectric layer 170b may be made of the same material and formed simultaneously in the same process. The “floating” gate means the terminal of the conductor in the decoupling capacitor is not electrically connected to a fixed reference, and thus it has an floating voltage.

As shown in FIG. 6B, the insulating layer 173 covers the floating gate layers 171 but does not cover the first gate electrode layers 172a. In addition, the second gate electrode layer 172b covers the insulating layer 173 and the first gate electrode layers 172a on the second fin structure 104b. The insulating layer 173 is located between the floating gate layers 171 and the second gate electrode layer 172b, and the first gate electrode layers 172a of the second fin structure 104b are electrically connected to the second gate electrode layer 172b. That is to say, the insulating layer 173 and the floating gate layers 171 are only formed in the decoupling capacitor 150 but not in the gate-all-around (GAA) structure 152.

The first gate dielectric layer 170a surrounds the first semiconductor layers 116a, and the floating gate layers 171, the insulating layer 173 and the second gate electrode layer 172b are formed on the first gate dielectric layers 170a. Therefore, the second gate electrode layer 172b, the insulating layer 173 and the floating gate layers 171 form a metal-insulator-metal (MIM) capacitor (i.e., an external capacitor), and the first semiconductor layers 116a, the first gate dielectric layers 170a and the floating gate layers 171 can form an internal capacitor connected to each other in series. The MIM capacitor and the internal capacitor are connected in series, thereby increasing the decoupling capability during high-voltage operation. In some embodiments, an interfacial layer 122 (IL) (not shown) is formed between the first gate dielectric layer 170a and the exposed surface of the first semiconductor layer 116a, and is formed between the second gate dielectric layer 170b and the exposed surface of the first channel layer 116b. In this case, the interfacial layer 122 can also be formed on the fins of the substrate 102. The interfacial layer 122 may include or be made of oxygen-containing materials or silicon-containing materials, such as silicon oxide, silicon oxynitride, oxynitride, hafnium silicate, and the like. The interfacial layer 122 can be formed by CVD, ALD, cleaning process or any suitable process. In some embodiments, the first and second gate dielectric layers 170a, 170b include one or more layers of dielectric materials, such as silicon oxide, silicon nitride, high-k dielectric materials, other suitable dielectric materials and/or combinations thereof. Examples of high-k dielectric materials include HfO₂, HfSiO, HfSiON, HfTaO, HfTiO, HfZrO, zirconia, alumina, titania, hafnium dioxide-alumina (HfO₂—Al₂O₃) alloys, other suitable high-k dielectric materials and/or combinations thereof. The first and second gate dielectric layers 170a, 170b may be formed by CVD, ALD, or any suitable deposition technique.

The first and second gate electrode layers 172a, 172b may include one or more layers of conductive materials, such as polycrystalline silicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloys, other suitable materials and/or any combination thereof. The first and second gate electrode layers 172a and 172b may be formed by CVD, ALD, electroplating or other suitable deposition techniques.

Referring to FIGS. 7A to 7D, schematic diagrams of a method of manufacturing a decoupling capacitor 150 are illustrated. First, FIG. 7A is shown based on the manufacturing process of the semiconductor structure shown in FIGS. 2B to 5B. First, a plurality of first semiconductor layers 116a and a plurality of second semiconductor layers 118 stacked alternately are formed on the first fin structure 104a (as shown in FIGS. 2B to 4B), and then remove the second semiconductor layers 118 to form openings 166 between adjacent first semiconductor layers 116a (as shown in FIG. 5B). Next, a plurality of first gate dielectric layers 170a is formed, and the first gate dielectric layers 170a respectively surround the first semiconductor layers 116a. In addition, the interfacial layers 122 may be formed between the first gate dielectric layer 170a and the first semiconductor layer 116a.

Next, in FIG. 7B, a plurality of floating gate layers 171 is formed. The floating gate layers 171 are electrically connected to each other and respectively surround the first gate dielectric layers 170a. The first gate dielectric layers 170a are respectively located between the first semiconductor layers 116a and the corresponding floating gate layers 171. Next, in FIG. 7C, an insulating layer 173 is formed to cover the floating gate layers 171. Next, in FIG. 7D, a second gate electrode layer 172b is formed. The second gate electrode layer 172b covers the insulating layer 173. The insulating layer 173 is located between the floating gate layers 171 and the second gate electrode layer 172b. Through the above-mentioned semiconductor process, the decoupling capacitor 150 can be formed on the first fin structure 104a, which has a fully surrounding floating gate layers 171 and a second gate electrode layer 172b with an enlarged equivalent area, and has an insulating layer 173 with a high dielectric constant (k is greater than 3.9), so that the equivalent capacitance value of the decoupling capacitor 150 can be greater than the capacitance value of a conventional capacitor without the floating gate layers 171 and the insulating layer 173. In one embodiment, the equivalent capacitance value of the decoupling capacitor 150 is proportional to its equivalent area. The area of the second gate electrode layer 172b is the sum of the total surface area of the second gate electrode layer 172b covering the insulating layer 173 (the sum of the areas in the three dimensions of length, width, and height), and the area of the floating gate layers 171 is the total surface area formed in the directions of the channel length, the width of the first semiconductor layer 116a, and the total height of the floating gate layer 171. Since the equivalent area of the second gate electrode layer 172b is increased, which is approximately 1.5 times to 3 times of the equivalent area of the internal capacitor, and the available area is maximized, the equivalent capacitance value of the decoupling capacitor 150 will also become larger. In one embodiment, the equivalent capacitance value of the decoupling capacitor 150 is approximately 1.5 times of that of a conventional capacitor without the floating gate layers 171 and the insulating layer 173, but the present disclosure is not limited thereto.

Referring to FIGS. 8A to 8F, which are schematic diagrams of a method of manufacturing a decoupling capacitor 150 that is compatible with the semiconductor manufacturing process. The following process only illustrates how to manufacture the insulating layer 173 and the second gate electrode layer 172b, the remaining parts have been explained in the above embodiments, please refer to the above. In FIG. 8A, the decoupling capacitor 150 includes a plurality of first semiconductor layers 116a, a plurality of first gate dielectric layers 170a and a plurality of floating gate layers 171 disposed on the first fin structure 104a, and the gate-all-around structure 152 includes a plurality of first channel layers 116b, a plurality of second gate dielectric layers 170b and a plurality of first gate electrode layers 172a disposed on the second fin structure 104b. The floating gate layer 171 and the first gate electrode layer 172a may be made of the same material and formed simultaneously in the same process. In FIG. 8B, the insulating layer 173 is comprehensively formed on the first fin structure 104a and the second fin structure 104b to cover the decoupling capacitor 150 and the gate-all-around structure 152. In FIG. 8C, a photoresist layer 178 is formed on a part of the insulating layer 173 that covers the floating gate layer 171, and the photoresist layer 178 is patterned to expose another part of the insulating layer 173 that covers first gate electrode layers 172a. That is, the photoresist layer 178 covers the decoupling capacitor 150 but does not cover the gate-all-around structure 152. In FIG. 8D, the part of the insulating layer 173 that covers the first gate electrode layers 172a is etched to retain the part of the insulating layer 173 that covers the floating gate layer 171. That is to say, the insulating layer 173 covers the floating gate layers 171 but does not cover the first gate electrode layers 172a. In FIG. 8E, the photoresist layer 178 is removed. In FIG. 8F, a second gate electrode layer 172b is formed. The second gate electrode layer 172b covers the insulating layer 173 and the first gate electrode layers 172a on the second fin structure 104b. The insulating layer 173 is located between the floating gate layers 171 and the second gate electrode layer 172b, and the first gate electrode layers 172a and the second gate electrode layer 172b are electrically connected. That is to say, in the decoupling capacitor 150, the second gate electrode layer 172b serves as the conductive metal of the MIM capacitor for connecting to a metal layer. However, in the gate-all-around structure 152, the first gate electrode layer 172a and the second gate electrode 172b both serve as a gate to control the first channel layers 116b to be turned on or off.

In one embodiment, the thicknesses of the first semiconductor layer 116a and the first channel layer 116b are respectively about 3 nm to 10 nm, and the thickness between the first semiconductor layer 116a and the adjacent first semiconductor layer 116a is about 4 nm to 20 nm, the thickness between the first channel layer 116b and the adjacent first channel layer 116b is about 4 nm to 20 nm. The thickness of the interfacial layer 122 is about 5 to 20 Angstroms. The thicknesses of the first and second gate dielectric layers 170a, 170b are about 5 to 30 Angstroms, the thickness of the floating gate layer 171 is about 1 nm to 9 nm, and the thickness of the first gate electrode layer 172a is about 1 nm to 9 nm. The thickness of the insulating layer 173 is about 5 to 30 Angstroms. The thickness of the second gate electrode layer 172b is about 5 Angstroms to a distance relative to the trench wall. In one embodiment, the thickness of the floating gate layer 171 is greater than the thickness of the first gate dielectric layers, and the thickness of the first gate electrode layer 172a is greater than the thickness of the second gate dielectric layers.

The present disclosure is directed to a semiconductor device, such as a decoupling capacitor, and a method of manufacturing the decoupling capacitor, which is compatible with a semiconductor manufacturing process for GAA-FET devices. The proposed architecture of decap is achieved by inserting of floating gate layers which are merged in the sheet-to-sheet spaces and capping by following IO dielectric layer (e.g., insulating layer) and gate electrode layer out of the sheet-to-sheet spaces. The floating gate layers can reduce possible capacitance loss at high frequency operation owing to better metal resistance with greater metal volume in space between sheet to sheet. Further, the high channel inversion capacitance of GAA-FET device is kept even at high frequency operation owing to acceptable metal resistance in the sheet-to-sheet spaces and the semiconductor device itself is also affordable for high voltage operation because most of voltage drop is sharing by enough thick IO dielectric layer out of the sheet-to-sheet spaces and is less constrained in gap fill space.

According to some embodiments of the present disclosure, a method of manufacturing a semiconductor device is provided. A plurality of first semiconductor layers and a plurality of second semiconductor layers alternately stacked over a substrate are formed. The second semiconductor layers are removed to form openings between the first semiconductor layers. A plurality of gate dielectric layers is formed, and each of the gate dielectric layers surrounds one of the first semiconductor layers respectively. A plurality of floating gate layers is formed, the floating gate layers are electrically connected to each other and surround the gate dielectric layers respectively, and the gate dielectric layers are located between the first semiconductor layers and the floating gate layers respectively.

According to some embodiments of the present disclosure, a method of manufacturing a semiconductor device is provided. A plurality of first semiconductor layers and a plurality of second semiconductor layers alternately stacked over a substrate are formed. A plurality of first channel layers and another plurality of second semiconductor layers alternately stacked over the substrate are formed. The second semiconductor layers are removed to form openings between the first semiconductor layers and between the first channel layers. A plurality of first and second gate dielectric layers are formed, and the first and second gate dielectric layers surround the first semiconductor layers and the first channel layers respectively. A plurality of floating gate layers is formed on the first gate dielectric layers, the floating gate layers are electrically connected to each other and surround the first gate dielectric layers respectively, wherein the first gate dielectric layers are located between the first semiconductor layers and the floating gate layers respectively. A plurality of first gate electrode layers is formed on the second gate dielectric layers, and the first gate electrode layers surround the second gate dielectric layers respectively, wherein the second gate dielectric layers are located between the second semiconductor layers and the first gate electrode layers respectively.

According to some embodiments of the present disclosure, a semiconductor device is provided. The semiconductor device includes a plurality of first semiconductor layers spaced and vertically stacked over a substrate, a plurality of first gate dielectric layers surrounding the first semiconductor layers respectively, a plurality of floating gate layers, and an insulating layer covering the floating gate layers. The floating gate layers are electrically connected to each other and surround the first gate dielectric layers respectively, wherein the first gate dielectric layers are located between the first semiconductor layers and the floating gate layers respectively.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a plurality of first semiconductor layers and a plurality of second semiconductor layers alternately stacked over a substrate,
removing the second semiconductor layers to form openings between the first semiconductor layers;
forming a plurality of gate dielectric layers, each of the gate dielectric layers surrounding one of the first semiconductor layers respectively; and
forming a plurality of floating gate layers, wherein the floating gate layers are electrically connected to each other and surround the gate dielectric layers respectively, and the gate dielectric layers are located between the first semiconductor layers and the floating gate layers respectively.

2. The method according to claim 1, further comprising:
forming an insulating layer covering the floating gate layers; and
forming a gate electrode layer, wherein the gate electrode layer covers the insulating layer, and the insulating layer is located between the floating gate layers and the gate electrode layer.

3. The method according to claim 2, wherein the gate electrode layer, the insulating layer and the floating gate layers form a metal-insulator-metal (MIM) capacitor, wherein each of the floating gate layers is arranged in a ring shape.

4. The method according to claim 3, wherein the floating gate layers, the first gate dielectric layers and the first semiconductor layers form an inner capacitor connected to the MIM capacitor.

5. A method of manufacturing a semiconductor device, comprising:
forming a plurality of first semiconductor layers and a plurality of second semiconductor layers alternately stacked over a substrate,
forming a plurality of first channel layers and another plurality of second semiconductor layers alternately stacked over the substrate;
removing the second semiconductor layers to form openings between the first semiconductor layers and between the first channel layers;
forming a plurality of first and second gate dielectric layers, the first and second gate dielectric layers surrounding the first semiconductor layers and the first channel layers respectively;
forming a plurality of floating gate layers on the first gate dielectric layers, the floating gate layers being electrically connected to each other and surrounding the first gate dielectric layers respectively, wherein the first gate dielectric layers are located between the first semiconductor layers and the floating gate layers respectively; and
forming a plurality of first gate electrode layers on the second gate dielectric layers, and the first gate electrode layers surrounding the second gate dielectric layers respectively, wherein the second gate dielectric layers are located between the second semiconductor layers and the first gate electrode layers respectively.

6. The method according to claim 5, further comprising:
forming an insulating layer covering the floating gate layers but not covering the first gate electrode layers; and
forming a second gate electrode layer, the second gate electrode layer covers the insulating layer and the first gate electrode layers, wherein the insulating layer is located between the floating gate layers and the second gate electrode layer, and the first gate electrode layers are electrically connected to the second gate electrode layer.

7. The method according to claim 6, wherein the second gate electrode layer, the insulating layer and the floating gate layers form a metal-insulator-metal (MIM) capacitor.

8. The method according to claim 7, wherein the floating gate layers, the first gate dielectric layers and the first semiconductor layers form an inner capacitor.

9. The method according to claim 8, wherein the MIM capacitor and the inner capacitor are connected in series.

10. The method according to claim 6, wherein the first and second gate electrode layers and the second gate dielectric layers form a gate-all-around (GAA) structure.

11. The method according to claim 6, wherein forming the insulating layer comprises:
forming the insulating layer comprehensively on the floating gate layers and the first gate electrode layers;
forming a photoresist layer on the insulating layer and patterning the photoresist layer to expose a part of the insulating layer that covers the first gate electrode layers; and
etching the part of the insulating layer that covers the first gate electrode layers to retain another part of the insulating layer on the floating gate layers.

12. A semiconductor device, comprising:
a plurality of first semiconductor layers spaced and vertically stacked over a substrate;
a plurality of first gate dielectric layers surrounding the first semiconductor layers respectively;
a plurality of floating gate layers, the floating gate layers being electrically connected to each other and surrounding the first gate dielectric layers respectively, wherein the first gate dielectric layers are located between the first semiconductor layers and the floating gate layers respectively; and
an insulating layer covering the floating gate layers.

13. The semiconductor device according to claim 12, further comprising:
a plurality of first channel layers spaced and vertically stacked over the substrate;
a plurality of second gate dielectric layers surrounding the first channel layers respectively; and
a plurality of first gate electrode layers being electrically connected to each other and surrounding the second gate dielectric layers respectively, wherein the second gate dielectric layers are located between the first channel layers and the first gate electrode layers respectively.

14. The semiconductor device according to claim 13, further comprising:
a second gate electrode layer covering the insulating layer and the first gate electrode layers, wherein the insulating layer is located between the floating gate layers and the second gate electrode layer, and the second gate electrode layer is electrically connected to the first gate electrode layers.

15. The semiconductor device according to claim 14, wherein the first and second gate electrode layers and the second gate dielectric layers form a gate-all-around structure.

16. The semiconductor device according to claim 13, wherein the second gate electrode layer, the insulating layer and the floating gate layers form a metal-insulator-metal (MIM) capacitor.

17. The semiconductor device according to claim 16, wherein the floating gate layers, the first gate dielectric layers and the first semiconductor layers form an inner capacitor.

18. The semiconductor device according to claim 17, wherein the MIM capacitor and the inner capacitor are connected in series.

19. The semiconductor device according to claim 16, wherein second gate electrode layer serves as a conductive metal of the MIM capacitor.

20. The semiconductor device according to claim 16, wherein the floating gate layers serve as a conductive metal of the MIM capacitor that has a floating voltage.
